(19) United States
(12) Patent Application Publication
(10) Pub. No.: US 2020/0003980 A1
(43) Pub. Date: Jan. 2, 2020

(54) FIBER MANAGEMENT CARTRIDGE

(71) Applicant: NLIGHT, INC., Vancouver, WA (US)

(72) Inventors: Christopher Andrew Luetjen, Vancouver, WA (US); Nicolas Trent Meacham, Vancouver, WA (US); Shaun Cody Hampton, Vancouver, WA (US); Rodney Mark Stephens, Hillsboro, OR (US)

(73) Assignee: NLIGHT, INC., Vancouver, WA (US)

(21) Appl. No.: 16/452,403

(22) Filed: Jun. 25, 2019

Related U.S. Application Data
(60) Provisional application No. 62/691,451, filed on Jun. 28, 2018.

(51) Int. Cl. G02B 6/44; H01S 3/067; H01S 3/094; H01S 5/024

(52) U.S. Cl. CPC G02B 6/4439; H01S 3/06704; H01S 5/02423; H01S 3/094053; H01S 3/06708; H01S 3/094003

(57) ABSTRACT

Some embodiments may include a fiber management cartridge, comprising: a plurality of sheets of material arranged in a stack, each sheet including: a first section to fasten to a surface; and a second section to make movement relative to the surface when the first section is fastened to the surface, the second section to hold one or more loops of one or more optical fibers, respectively, of a fiber laser. Other embodiments may be disclosed and/or claimed.

### RELATED APPLICATIONS

This application is a non-provisional of and claims benefit to U.S. Provisional Application No. 62/691,451, filed Jun. 28, 2018, which is incorporated by reference herein in its entirety.

### TECHNICAL FIELD

The present disclosure relates to fiber lasers, and more particularly to a fiber management cartridge for a fiber laser.

### BACKGROUND

Fiber lasers are widely used in industrial processes (e.g., cutting, welding, cladding, heat treatment, etc.) In some fiber lasers, the optical gain medium includes one or more active optical fibers with cores doped with rare-earth element(s). The rare-earth element(s) may be optically excited (“pumped”) with light from one or more semiconductor laser sources.

Fiber lasers may also have multiple passive optical fibers, which can become entangled with each other; especially if the fiber laser is serviced. Entangling can cause microbends in the passive optical fibers, which may cause optical component failure and/or poor fiber laser performance.

### BRIEF DRAWINGS DESCRIPTION

The accompanying drawings, wherein like reference numerals represent like elements, are incorporated in and constitute a part of this specification and, together with the description, explain the advantages and principles of the presently disclosed technology.

FIG. 1 illustrates a top view of fiber management cartridge, according to some embodiments.

FIG. 2 illustrates optical fibers ingressing the fiber management cartridge at a first edge of the fiber management cartridge and egressing the fiber management cartridge at a second opposite edge of the fiber management cartridge.

FIG. 3 illustrates a block diagram of sheets of the fiber management cartridge with respect to their optical fibers in open and closed positions.

FIG. 4A illustrates an isometric view of the fiber management cartridge in a closed position.

FIG. 4B illustrates an isometric view of the fiber management cartridge in an open position.

FIG. 5 illustrates a fiber management assembly including the fiber arrangement cartridge mounted on a cold plate.

FIG. 6 illustrates a process for servicing a fiber laser including the fiber management cartridge.

### DETAILED DESCRIPTION

Some embodiments may include a fiber management cartridge; comprising: a plurality of sheets of material arranged in a stack, each sheet including: a first section to fasten to a surface; and a second section to make movement relative to the surface when the first section is fastened to the surface, the second section to hold one or more loops of one or more optical fibers, respectively, of a fiber laser. Other embodiments may be disclosed and/or claimed.

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items. The systems, apparatus, and methods described herein should not be construed as limiting in any way. Instead, the present disclosure is directed toward all novel and non-obvious features and aspects of the various disclosed embodiments, alone and in various combinations and sub-combinations with one another.

The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation. Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus.

Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art. In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

Sometimes the passive optical fibers of a fiber laser may be bundled into a mandrel or guide. The mandrel or guide may include a flat stationary surface on which one or more of the optical fibers, arranged in a coil, may be mounted. However, depending on the stiffness of the optical fiber and/or bend radius requirements (passive optical fibers may be constructed from drawn glass, and as such may have a bend radius specification to prevent damage), these coils may be large, and as such, may require a large mandrel or guide. Furthermore, depending on an optical fiber count of the fiber laser, it may be suitable to use more than one large mandrel or guide to avoid risks of entanglement.

Requirements for multiple large mandrels or guides may result in a bulky fiber laser. Therefore, to provide a compact fiber laser, an attempt may be made to coil multiple optical fibers together on a single mandrel or guide despite the risk of entanglement. However, this approach may increase the chance of entanglement and/or may make servicing such a compact fiber laser very difficult and/or expensive.

Some embodiments of a fiber management cartridge may allow passive optical fibers of a fiber laser to be affixed to thin sheets that are stacked on top of each other and bound along one axis. The thin sheet may rotate around this axis (and/or rotate around unlooped segments of the optical fibers) to provide access to optical fibers affixed to a lower sheet of the stack. All optical fibers may enter and exit along a same axis. The optical fibers of one sheet may all be on the same side of the sheet, or one or more the optical fibers may be on a different side of the sheet, according to various embodiments.

In some embodiments, the optical fiber may be secured to the thin sheet using pre-bent tabs having ends tucked into openings in the thin sheet. In other embodiments, the optical fibers may be secured using adhesive back tabs adhered to the thin sheet.

The fiber management cartridge may allow for all of the optical fibers to be accessible for serviceability. The fiber management cartridge may prevent the optical fibers from entangling with each other. In some embodiments, a fiber laser using a fiber management cartridge may be more compact, more servicable, less likely to experience failure from microbends, or the like, or combinations thereof, than a fiber laser having optical fibers bundled into a mandrel or guide.

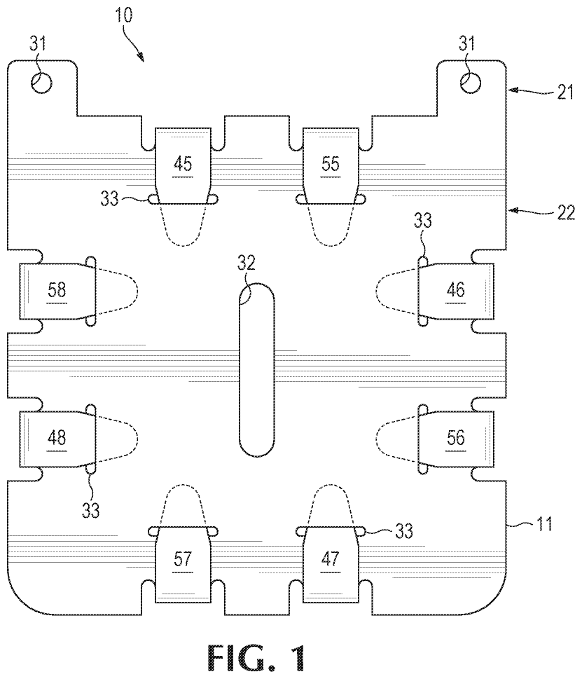

FIG. 1 illustrates a top view of fiber management cartridge 10, according to some embodiments. The cartridge 10 may include a plurality of sheets arranged in stack. In this view, only a sheet 11 of a top of the stack is shown, but the other sheets of the stack may be similar to sheet 11 in any respect.

The sheet 11 may include a first section 21 to fasten to a surface, such as a surface of a fiber laser. The first section 21 may include openings 31 to fasten the fiber management cartridge 10 to the surface. The openings 31 may be shaped and sized to receive projections (e.g., posts) mounted to the surface.

The sheet 11 may include a second section 22 extending from the first section 21. When the first section 21 is fastened to the surface, the second section 22 may make movement relative to the surface. The second section 22 may also be arranged to hold one or more loops (e.g., service loops) of one or more passive optical fibers (not shown), respectively, of a fiber laser. The second section 22 may be sized based on a bend radius specification of the optical fiber so that the optical fiber of the loops may not be subjected to a microbend while in the fiber management cartridge 10.

When the second section 22 of the sheet 11 is moved relative to the surface, e.g., when the second section 22 is pivoted on an axis by, for example, a person lifting one of the uncoupled edges of the second section 22 away from the surface, a next second section of a next sheet (not shown) may be exposed. One or more loops held by the next section of the next sheet may be accessed by the person. For example, if troubleshooting for a fiber laser indicates that an optical component corresponding to the optical fiber held by the next section of the next sheet has failed, the person can access this optical fiber (such access may be needed to replace or repair the failed optical component). The access to the one or more loops held by the next section of the next sheet may be made without removing one or more loops held by the second section 22 of the sheet 11, or any optical fibers of any other sheets. Accordingly, a number of optical fibers in the fiber management cartridge 10 may not be subject to any risk of a microbend (or a lower risk of a microbend than examples in which optical fibers are coiled around a single mandrel).

Furthermore, any number of sheets can be moved together relative to the surface to access an optical fiber of a sheet deeper in the stack. The sheet 11 and zero or more (e.g., N−2) next sheets can be moved to access an optical fiber of an Nth next sheet. The optical fibers of the sheet 11 and the zero or more next sheets may be pivoted but remain safely in the fiber management cartridge. Also, optical fibers of any next sheets deeper than the Nth next sheet also may remain safely in the fiber management cartridge (and may not move). In some examples, the fiber management cartridge 10 may include a total of four sheets, but other examples can have different counts.

In some examples, the second section 22 may include a number of projections (such as tabs 45-48 and 55-58) to fold over and insert into corresponding openings 33 in the second section 22 to secure loops of the second section 22 of the sheet 11. In the present example, a count of these projections of sheet 11 is eight, but in other examples different counts may be used. For example, in another example the count may be four an each projection may be centered on a corresponding one of four edges of a sheet.

In some examples, the sheet 11 may be manufactured by cutting a sheet of polypropylene (e.g., ESD-safe (electrostatic discharge) polypropylene sheets) into the sheet 11 with the tabs 45-48 and 55-58 unfolded and laying in a same plane as the rest of the sheet 11. The polypropylene may be pre-kinked at locations at which the tabs 45-48 and 55-58 are to be folded. Pre-kinking may be by coining (e.g., pressure based scoring). In some examples, pre-kinking may be along two parallel lines to allow the tabs to fold 90 degrees on each line in order to provide a compact height for each sheet. A distance between the parallel lines may be based on diameter of the optical fiber to be held by the tabs 45-48 and 55-58.

In some examples, it may be possible and practical to hold one loop of an optical fiber on one side of the second section 22 of the sheet 11 and hold another loop of another optical fiber on an opposite side (not shown) of the second section 22 of the sheet 11. In such an example, some of the tabs 45-48 and 55-58 (say, tabs 45-48) may be coined on one side of the polypropylene and other ones of the tabs 45-48 and 55-58 (say, tabs 55-58) may be coined on an opposite side of the polypropylene to provide folding in opposite directions.

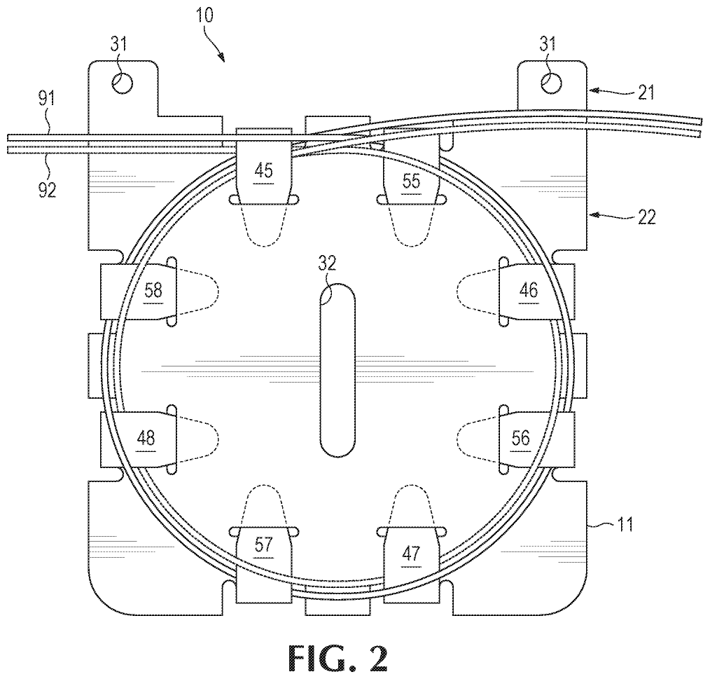

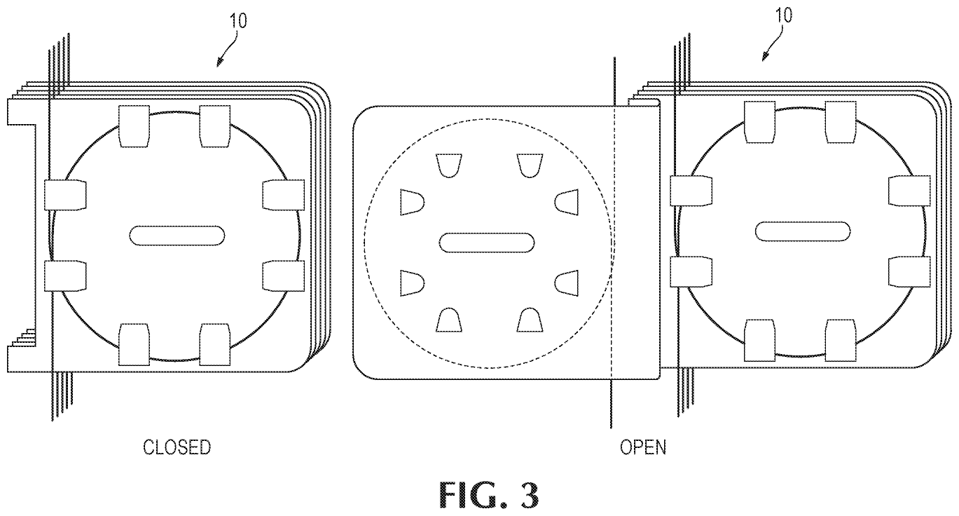

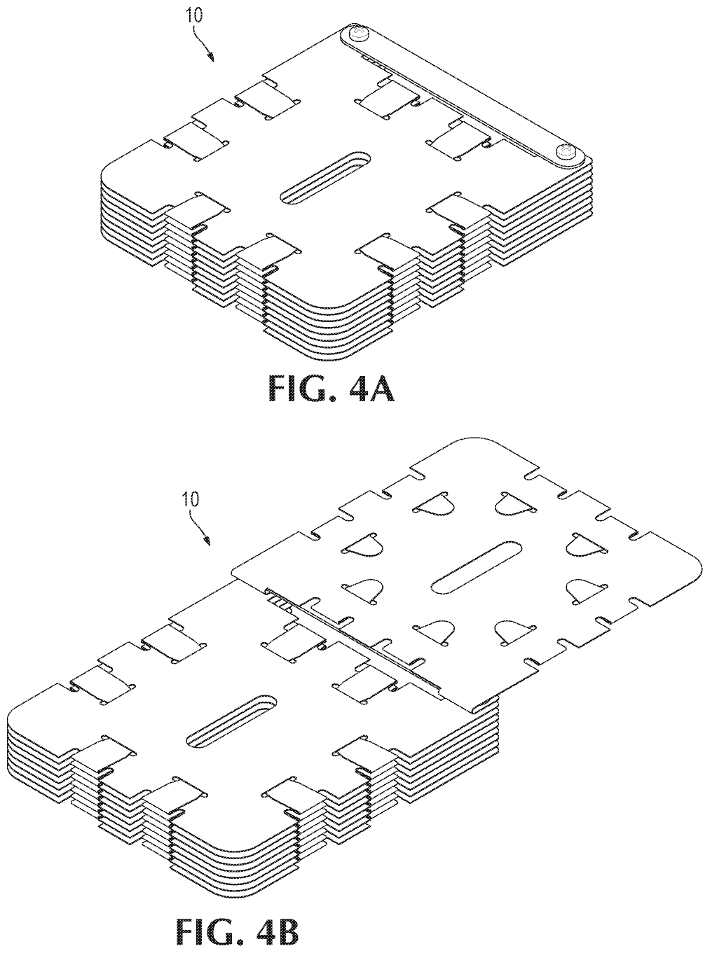

Referring again to the illustrated embodiment, and now referring to FIG. 2, a set 91 of one or more loops of one or more optical fibers and a set 92 of one or more loops of one or more optical fibers are shown held by the second section 22 (FIG. 1) of the sheet 11 (FIG. 1) of the fiber management cartridge 10. The optical fibers sets 91 and 92 ingress the fiber management cartridge 10 at a first side of the fiber management cartridge and egress the fiber management cartridge 10 at a second side that is opposite the first side. Such an arrangement may allow the loops to rotate around a single axis of the fiber management cartridge 10 when accessing loops other sheets. Unlooped segments of the optical fibers may be placed on this axis (and this axis may be located at a border between the first and second sections 11 and 22) such that the looped segments rotate around the unlooped segments. FIG. 3 illustrates a block diagram of sheets of the fiber management cartridge with respect to their optical fibers in open and closed positions. FIG. 4A illustrates an isometric view of the fiber management cartridge in a closed position, and FIG. 4B illustrates an isometric view of the fiber management cartridge in an open position.

Referring again to FIG. 2, in some examples, to optimize a number of loops held by a second section of a single sheet, the loops may be weaved differently though the 45-48 and 55-58. In this example, tabs 55, 56, 57, and 58 are folded over the one or more loops of optical fiber set 91 and the one or more loops of optical fiber 92 set is on these tabs 55, 56, 57, and 58. Tabs 45, 46, 47, and 48 are folded over the one or more loops of optical fiber set 92 and the one or more loops of optical fiber set 91 is on these tabs 45, 46, 47, and 48. This weaving may allow a subset of loops of a single sheet to be serviced without removing and/or damaging another subset of loops of the same sheet.

In some examples, each of the sets 91 and 92 may include two optical fibers. The optical fibers of one of the sets 91 and 92 may all be of a same channel (e.g., LED (light-emitting diode) channel) of the optical gain medium.

Referring again to FIG. 1, the second section 22 may have at least one opening 32, which may receive a projection sized similar to the projections received by the openings 31 (to prevent the second section 22 from moving relative to the surface during, say, transit of the fiber laser). Although the opening 32 may receive a similarly sized projection, the opening 32 may have a different shape and/or size than the openings 31 of the first section. In this example, the opening 32 is stadium shaped and the post may be located at an end of the opening 32 closest to the first section 21 in the closed position (in the fully open position a higher point along the post may be located at an opposite end of the opening 32).

Although in this example the second seconds of other sheets of the fiber management cartridge 10 may be the similar to second section 22 of sheet 11, this is not required. In some examples, if a fiber management cartridge may be used to hold optical fibers with heterogeneous bend radius requirements (say, at least one optical fiber may be thicker than at least one another optical fiber), and at least one sheet of the fiber management cartridge may have a larger and/or differently shaped second section than a second section of at least one other sheet of the fiber management cartridge.

In the illustrated example, the first and section sections 21 and 22 have a same width and thickness, but this is not required (in other examples, the second section 22 may have a width and/or thickness that is different than a width and/or thickness of the second section 22. In the illustrated example, the second section 22 has a square profile. In other examples, the second section 22 may have a different profile, such as a substantially circular profile.

In some examples, the fiber management cartridge 10 may employed in a fiber laser (e.g., affixed to a surface of the fiber laser) to enable a compact, servicable fiber laser. In other examples, the fiber management cartridge 10 may be employed in other environments for storage. For example, the fiber management cartridge 10 may be used in a warehouse or service center to store optical fiber that is not yet coupled to a fiber laser. The fiber management cartridge 10 may hold lengths of optical fiber to be used for fiber laser service.

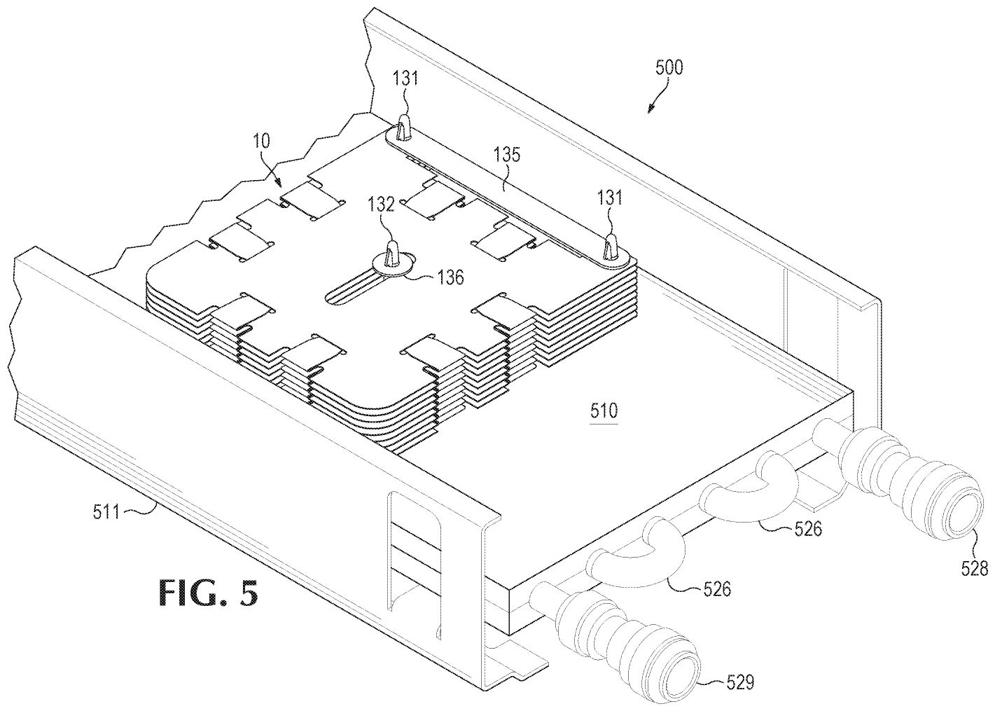

FIG. 5 illustrates a fiber management assembly 500 including the fiber management cartridge 10 mounted on a side 510 of a cold plate 511 (a portion of the cold plate 511 is illustrated). Mounting on the cold plate 511 may be desirable in some applications for a number of considerations (such as backward compatibility, field replicability, routing, or the like, or combinations thereof), but is not required. In other examples, depending on application, the fiber management cartridge 10 may be mounted to any surface of a fiber laser.

The fiber management cartridge 10 allows a relatively small area of a surface, such as a small area of the cold plate 511, to hold a large number of loops (e.g., service loops) of optical fibers where the length of optical fiber in the fiber management cartridge 10 is a “service length” of passive optical fiber. The service length provides serviceability options.

In an example of servicing, consider an example in which a pump laser (active optical fiber) of a fiber laser has failed. In order to replace the pump laser, passive optical fiber may be cut to remove the failed pump laser. It may be desirable to replace the cut passive optical fiber for reliability reasons while replacing the pump laser, in some examples. The passive optical fiber to be replaced may be removed from the fiber management cartridge 10 by turning to the appropriate sheet and releasing the appropriate tabs. A new optical fiber may be inserted into the appropriate sheet and closing the appropriate tabs. In other examples, it may be possible to re-use the same passive optical fiber. However, in other case, a splice tool may be needed during the service (to splice in the new passive optical fiber or to re-splice the passive optical fiber if re-used). In order to use the splice tool, in some examples a service length of passive optical fiber may be needed in order to use the splice tool (say, a one meter length), which may be positioned adjacent to the fiber laser. Due to the service length of the loop (e.g., the service loop, realized by looping an optical fiber one or more times in the fiber management cartridge 10 as needed to provide the required service length), the passive optical fiber may be long enough to use the splice tool. Thus, a small footprint fiber management cartridge 10 including the service lengths in the loops provides serviceability of a fiber laser using a splice tool.

Posts 131 and 132 may be attached to a surface of the side 510 by, for example, screwing threaded ends of posts 131 and 132 to threaded holes in the surface. The fiber management cartridge 10 may be coupled to the posts 131 and 132 at the openings 31 and 32 (FIG. 1), respectively. Clips 135 and 136 may be used to releasably secure the fiber management cartridge 10 to the cold plate 511. The clips 135 and 136 may be secured to the posts 131 and 132 using any fastener, such as a standoff screwed to threaded ends of tops of the posts 131 and 132 to drive the clips 135 and 136 an appropriate distance based on a thickness of the fiber management cartridge 10 (which may be based on a selectable count of sheets and/or a selectable amount of optical fibers to be held by the fiber management cartridge 10).

The cold plate 511 may have active cooling, such as convection cooling with piping 526 to route liquid to carry away heat. In operation, an inlet 528 may deliver the liquid and an outlet may output the heated liquid. In one example, the cooling plate 511 may cool optical components (not shown, such a combiner, a beam dump, or the like, or combinations thereof) that may be mounted on the side 510 and/or the opposite side of the cooling plate 511.

Passive optical fibers spliced to one or more optical components (not shown) of a fiber laser may ingress one side of the optical management cartridge and egress the other side similar to FIG. 2. Referring again to FIG. 5, the passive optical fibers egressing the fiber management cartridge 10 (say, at an edge closest to the illustrated piping 526) may be placed in a 180 degree loop. The passive optical fibers may continue from the 180 degree loop away from the illustrated piping 526 and between the optical management cartridge 10 and the edge of the surface 510 and away from the optical management cartridge 10 where they may be spliced to one or more other optical components (not shown) of the fiber laser.

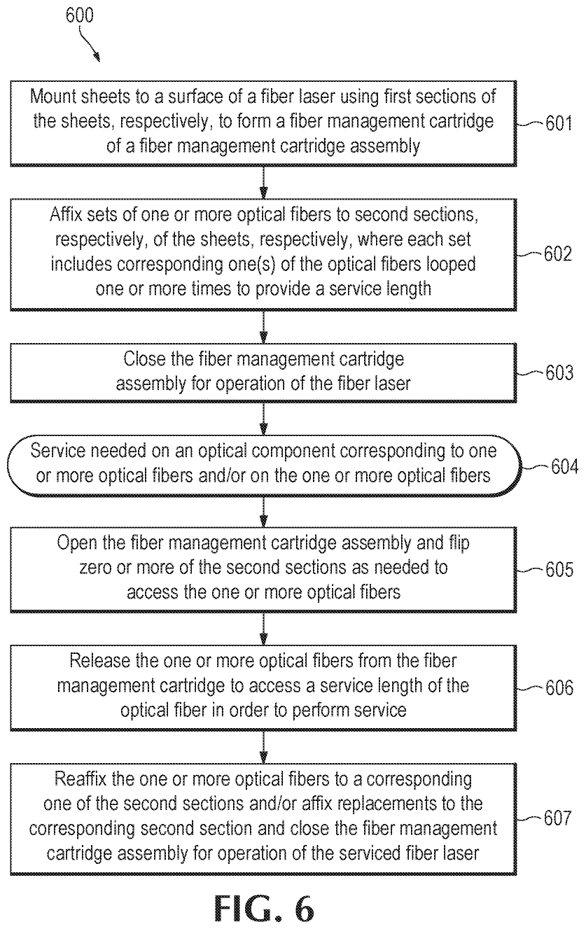

FIG. 6 illustrates a process 600 for servicing a fiber laser including the fiber management cartridge 10 (FIG. 1). In block 601, sheets may be mounted to a surface of fiber laser using first sections of the sheets, respectively, to form a fiber management cartridge of a fiber management cartridge assembly. In block 602, sets of one or more optical fibers may be affixed to second sections, respectively, of the sheets, respectively. Each set may include corresponding one(s) of the optical fibers looped one or more times to provide a service length. In block 603, the person may close the fiber management cartridge assembly.

At some time, service may be needed on an optical component corresponding to one or more optical fibers and/or on the one or more optical fibers, as indicated by oval 604. In block 605, the fiber management cartridge assembly may be opened and zero or more of the second sections may be flipped as needed to access the one or more optical fibers. In block 606, the one or more optical fibers may be released from the fiber management cartridge (say, a subset of optical fibers of a side of the sheet) to access a service length of the one or more optical fibers in order to perform the service. In block 607, the one or more optical fibers may be reaffixed to a corresponding one of the second sections and/or affix one or more replacement optical fibers to the corresponding second section, and the fiber management cartridge assembly may be closed for operation of the serviced fiber laser.

In view of the many possible embodiments to which the principles of the disclosed technology may be applied, it should be recognized that the illustrated embodiments are only preferred examples and should not be taken as limiting the scope of the disclosure. We claim as our invention all that comes within the scope and spirit of the appended claims.

1. An apparatus, comprising:
a plurality of optical fibers to optically couple to an optical fiber medium of a fiber laser, each of the optical fibers including a segment arranged in a loop; and
a fiber management cartridge including a plurality of sheets of material arranged in a stack, each sheet having a first section and a second section, the first sections of the sheets to fasten to a surface and the second sections to make movement relative to the surface when the first sections are fastened to the surface; and
wherein one or more of the loops of one or more first optical fibers, respectively, of the plurality of optical fibers is affixed to a first side of the second section of a first sheet of the plurality of sheets, and one or more of the loops of one or more second different optical fibers, respectively; of the plurality of optical fibers is affixed to a first side of the second section of a second different sheet of the plurality of sheets.

2. The apparatus of claim 1, wherein one or more of the loops of one or more third optical fibers, respectively, of the plurality of optical fibers is affixed to a second opposite side of the second section of the first sheet or the second sheet.

3. The apparatus of claim 1, further comprising:
one or more openings in the first sections to fasten the first sections of the sheets to the surface, the one or more openings arranged to receive one more vertical posts, respectively, arranged on the surface.

4. The apparatus of claim 1, further comprising:
one or more openings in each of the second sections;
wherein one or more edges of each sheet include one or more tabs to fold over and insert into the one or more openings, respectively, to secure corresponding ones of the loops.

5. The apparatus of claim 1, further comprising:
sets of openings located proximate to edges, respectively, of each sheet;
wherein each set of openings includes one or more openings; and
wherein each edge includes one or more tabs to fold over and insert into the one or more openings of a corresponding one of the sets of openings, respectively, to secure corresponding ones of the loops.

6. The apparatus claim 5, wherein a count of the tabs of each sheet is equal to four.

7. The apparatus of claim 5, wherein a count of the tabs of each sheet is equal to eight.

8. The apparatus of claim 1, wherein a count of the sheets is greater than two.

9. The apparatus of claim 1, wherein the optical fibers ingress the fiber management cartridge at a first edge of the fiber management cartridge and egress the fiber management cartridge at a second opposite edge of the stack.

10. The apparatus of claim 1, wherein the sheets comprise sheets of polypropylene.

11. A fiber management cartridge, comprising:
a plurality of sheets of material arranged in a stack, each sheet including:
a first section to fasten to a surface; and
a second section to make movement relative to the surface when the first section is fastened to the surface, the second section to hold one or more loops of one or more optical fibers, respectively, of a fiber laser.

12. The fiber management cartridge of claim 11, further comprising:
one or more openings in each of the second sections;
wherein one or more edges of each sheet include one or more tabs to fold over and insert into the one or more openings, respectively, to secure corresponding ones of the loops.

13. The fiber management cartridge of claim 11, further comprising:
sets of openings located proximate to edges, respectively, of each sheet;
wherein each set of openings includes one or more openings; and
wherein each edge includes one or more tabs to fold over and insert into the one or more openings of a corresponding one of the sets of openings, respectively, to secure corresponding ones of the loops.

14. The fiber management cartridge of claim 11, wherein the second section is larger than the first section.

15. The fiber management cartridge of claim 11, further comprising:
one or more openings in the first sections to fasten the first sections of the sheets to the surface, the one or more openings arranged to receive one more vertical posts, respectively, arranged on the surface.

16. A compact, serviceable fiber laser, comprising:
at least one active optical fiber to generate laser light;
a plurality of passive optical fibers optically coupled to the at least one active optical fiber, each of the passive optical fibers including a section arranged in a loop; and
a fiber management cartridge including a plurality of sheets of material arranged in a stack, each sheet comprising:
a first section mounted to a surface of the fiber laser; and
a second section to make movement relative to the surface of the fiber laser when the first section is mounted to the surface of the fiber laser;
wherein the loops of the plurality of passive optical fibers are mounted to the second sections.

17. The fiber laser of claim 16, further comprising:
a plurality of first projections arranged on the surface of the fiber laser, the first projections puncturing openings in the first sections; and
at least one second projection arranged on the surface of the fiber laser, the at least one second projection puncturing an opening of each of the second sections.

18. The fiber laser of claim 17, wherein the openings in the second sections are larger than the openings in the first sections.

19. The fiber laser of claim 16, wherein the surface comprises a side of a cooling plate, wherein the side of the cooling plate comprises a first side of the cooling plate, and wherein the fiber laser includes at least one optical component coupled to a second opposite side of the cooling plate.

20. The fiber laser of claim 16, wherein the passive optical fibers ingress the fiber management cartridge at a first edge of the fiber management cartridge and egress the fiber management cartridge at a second opposite edge of the fiber management cartridge.
